(19) United States
(12) Patent Application Publication
(10) Pub. No.: US 2014/0078702 A1
(43) Pub. Date: Mar. 20, 2014

(54) MULTILAYER PRINTED CIRCUIT BOARD

(71) Applicant: Sony Corporation, Tokyo (JP)

(72) Inventor: Satoshi Mizuno, Tokyo (JP)

(73) Assignee: Sony Corporation, Tokyo (JP)

(21) Appl. No.: 14/024,031

(22) Filed: Sep. 11, 2013

(30) Foreign Application Priority Data
Sep. 18, 2012 (JP) 2012203962

(51) Int. Cl. H05K 1/02

(52) U.S. Cl. CPC H05K 1/0213
USPC 361/760

(57) ABSTRACT

A multilayer printed circuit board having multiple layers includes: a chip mounted on a top layer of the printed circuit board; and at least a conductor connected to a power supply and a conductor connected to a ground as conductors printed on the respective layers, wherein a power plane that is the conductor connected to the power supply and that is not patterned is provided on a lower area of the chip on the top layer.

### CROSS REFERENCE TO RELATED APPLICATIONS

This application claims the benefit of priority under 35 U.S.C. §119 from Japanese Priority Patent Application JP 2012-203962, filed on Sep. 18, 2012, the entire contents of which are incorporated herein by reference.

### TECHNICAL FIELD

The present technology relates to a multilayer printed circuit board, and more particularly, to a multilayer printed circuit capable of improving impedance characteristics thereof.

### BACKGROUND ART

Memories compatible with standards such as DDR (Double Data Rate), DDR2, mDDR, and DDR3 capable of reading/writing data at high speed are recently mounted on more and more electronic devices. Such a memory is placed on a multilayer printed circuit board provided in an electronic device and having multiple layers.

A multilayer printed circuit board includes insulators and patterns that are stacked like wafers, in which components are mounted at higher density and the number of layers is increased so as to accommodate circuit wiring that may not be sufficiently accommodated only on both faces of the board as circuit connections become more complex. In a case of a four-layer printed board, two inner layers are often used as a power layer and a ground layer and signal lines are often arranged on two surface layers (outer layers) so that the impedance of a signal can be controlled.

A multilayer printed circuit board is provided with layers such as a power layer on which a power pattern that is a pattern connected to a power supply is provided and a ground layer on which a ground pattern that is a pattern connected to the ground is provided. In a four-layer printed circuit board, for example, one power layer and one or two ground layers are provided as inner layers of the multilayer printed circuit board.

Specifically, in a case where one power layer and two ground layers are provided in a four-layer through-hole board or build-up board as a printed circuit board, an L1 layer provided on a surface of the printed circuit board and an L2 layer adjacent to and under the L1 layer are ground layers. An L3 layer adjacent to and under the L2 layer is a power layer and an L4 layer adjacent to and under the L3 layer is a solder ball layer.

Recently, more than one power plane is formed in a multilayer printed circuit board, and power planes and ground planes on inner layers of a multilayer printed board are often divided.

Furthermore, a technology for reducing occurrence of radiation noise by arranging an inductance pattern at an optimum position is proposed (refer, for example, to PTL 1).

### CITATION LIST

### Patent Literature

[PTL 1]

JP 9-326451 A

### SUMMARY

### Technical Problem

With a multilayer printed circuit board, however, it is not easy to prevent the impedance from increasing. When a multilayer printed circuit board is used for a DDR2 memory or the like, an increase in the impedance of the printed circuit board is a factor that worsens simultaneous switching output noise (SSO) jitter, that is, jitter caused by simultaneous switching noise, clock jitter, noise between a power supply and the ground, and the like.

Furthermore, as the data transfer rate becomes higher, it is increasingly difficult to suppress jitter of a signal so that a multilayer printed circuit board is compatible with a standard such as the DDR, and it is necessary to improve the impedance characteristics of multilayer printed circuit boards.

With a multilayer printed circuit board of related art, in the case of a four-layer substrate package, the vicinity of a power pad of an L1 layer has wiring as a GND plane (solid) and only one inner layer is used for the power supply, which makes it difficult to improve impedance characteristics. Furthermore, since the pads are placed so that wire bonding to GND becomes shortest in preference to the power supply, it is particularly difficult to improve the impedance characteristics of the power supply.

The present technology is disclosed in view of the aforementioned circumstances and allows the impedance characteristics of a multilayer printed circuit board to be improved.

### Solution to Problem

An aspect of the present technology is a multilayer printed circuit board having multiple layers, including: a chip mounted on a top layer of the printed circuit board; and at least a conductor connected to a power supply and a conductor connected to a ground as conductors printed on the respective layers, wherein a power plane that is the conductor connected to the power supply and that is not patterned is provided on a lower area of the chip on the top layer.

Out of second pads wire-bonded to pads on the chip provided on the top layer, a first second pad wire-bonded to a pad connected to the power supply may be arranged nearer to an edge of the chip than a second second pad wire-bonded to a pad connected to the ground.

Multiple solder balls may be provided on a bottom layer opposite to the top layer of the multilayer printed circuit board, and when positions on front surfaces of the respective layers of the multilayer printed circuit board having identical rectangular shapes, the positions corresponding to those of the first second pads on the top layer, are expressed by using two-dimensional coordinates, the solder balls on the bottom layer may be provided at substantially same coordinate positions as those where the first second pads are arranged on the top layer.

Out of second pads wire-bonded to pads on the chip provided on the top layer, multiple second pads wire-bonded to pads connected to power supplies of equal voltage may be arranged close to one another as a group of second pads, and the group of second pads may be connected to another layer through one via.

The chip on which pads connected to the power supply are arranged at an outermost portion of and in parallel to an edge of the chip may be mounted on the top layer.

The pads arranged at the outermost portion of the chip may include pads connected to the ground, and pads adjacent to both sides of the pads connected to the ground may be pads connected to the power supply.

According to an aspect of the present technology, a chip is mounted on a top layer of a printed circuit board having multiple layers, at least a conductor connected to a power supply and a conductor connected to a ground are included as conductors printed on the respective layers, and a power plane that is the conductor connected to the power supply and that is not patterned is provided on a lower area of the chip on the top layer.

### Advantageous Effects of Invention

According to an aspect of the present technology, the impedance characteristics of a multilayer printed circuit board can be improved.

### BRIEF DESCRIPTION OF DRAWINGS

FIG. 1 is a sectional view for explaining an exemplary structure of a package substrate to which the present technology is applied.

FIG. 2 is a view showing an example of a wiring pattern of an L1 layer of a multilayer printed circuit board of related art.

FIG. 3 is a view showing an example of a wiring pattern of an L1 layer of a multilayer printed circuit board to which the present technology is applied.

FIG. 4 is an enlarged view of an upper-right part of a chip lower area in FIG. 3.

FIG. 5 is a view showing an example of a wiring pattern of an L2 layer of the multilayer printed circuit board to which the present technology is applied.

FIG. 6 is a view showing an example of a wiring pattern of an L3 layer of the multilayer printed circuit board to which the present technology is applied.

FIG. 7 is a view showing an example of a wiring pattern of an L4 layer of the multilayer printed circuit board to which the present technology is applied.

FIG. 8 is a diagram showing an exemplary schematic arrangement of pads on a chip and second pads on the L1 layer of the multilayer printed circuit board to which the present technology is applied.

FIG. 9 is a diagram showing another exemplary schematic arrangement of pads on the chip and second pads on the L1 layer of the multilayer printed circuit board to which the present technology is applied.

FIG. 10 is a diagram for explaining an arrangement of a solder ball on a rear face of the L4 layer.

FIG. 11 is a table showing the inductance value and the capacitance value of each of DDR power supply and GND in a package substrate to which the present technology is applied.

FIG. 12 is a graph showing a result of measuring loop impedance of a package substrate to which the present technology is applied.

FIG. 13 is a circuit diagram of a package substrate that serves as an LSI of a DDR memory.

FIGS. 14A and 14B are graphs showing eye patterns of a DDR input terminal obtained with the circuit of FIG. 13.

### DESCRIPTION OF EMBODIMENTS

Embodiments of the present technology disclosed herein will be described below with reference to the drawings.

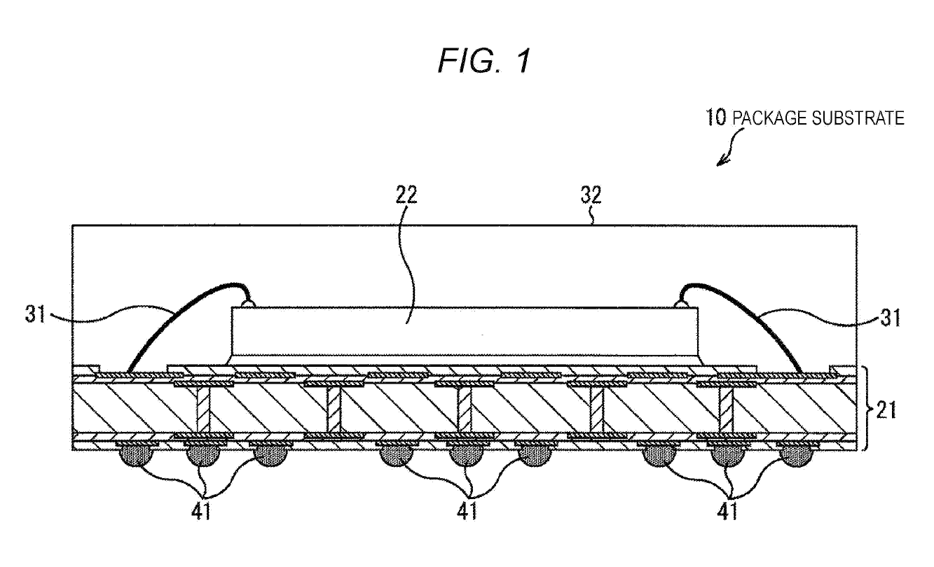

FIG. 1 is a sectional view for explaining an exemplary structure of a package substrate to which the present technology is applied. A package substrate 10 shown in FIG. 1 is used for a DDR (Double Data Rate) 2, mDDR, or DDR 3 memory, for example.

The package substrate 10 shown in FIG. 1 includes an interposer 21 that is a multilayer printed circuit board, a chip 22 mounted on the interposer 21, and resin 32 filled around the chip 22.

The chip 22 has multiple pads provided on a front face thereof (the upper face in the drawing), and the interposer 21 also has multiple pads (referred to as second pads) provided on a front face thereof (the upper face in the drawing). The pads on the chip 22 and the second pads on the interposer 21 are connected using wire bonding. In the example of FIG. 1, the pads on the chip 22 and the second pads on the interposer 21 are connected by wires 31. Although only two wires 31 are illustrated in the example of FIG. 1, there are actually a large number of wires.

Furthermore, the chip 22 has multiple solder balls 41 on a rear face thereof (the lower face in the drawing). The package substrate 10 is electrically connected to a motherboard or the like provided below the package substrate 10 via the solder balls 41, for example.

As described above, the interposer 21 is a multilayer printed circuit board. Specifically, the interposer 21 includes multiple layers, such as four layers of an L1 layer, an L2 layer, an L3 layer, and an L4 layer in this order from the top. Each of the L1 to L4 layers has a wiring pattern specific thereto printed thereon, and insulating layers made of an insulator are provided between the layers.

A multilayer printed circuit board includes insulators and patterns that are stacked like wafers, in which parts are mounted at higher density and the number of layers is increased so as to accommodate circuit wiring that may not be sufficiently accommodated only on both faces of the board as circuit connections become more complex. In a case of a four-layer printed board, two inner layers are often used as a power layer and a ground layer and signal lines are often arranged on two surface layers (outer layers) so that the impedance of a signal can be controlled.

A multilayer printed circuit board is provided with layers such as a power layer on which a power pattern that is a pattern connected to a power supply is provided and a ground layer on which a ground pattern that is a pattern connected to the ground is provided. In a four-layer printed circuit board, for example, one power layer and one or two ground layers are provided as inner layers of the multilayer printed circuit board.

In related art, in a case where one power layer and two ground layers are provided in a four-layer through-hole board or build-up board as a printed circuit board, an L1 layer and an L2 layer of the printed circuit board are ground layers, an L3 layer thereof is a power layer, and an L4 layer thereof is a solder ball layer.

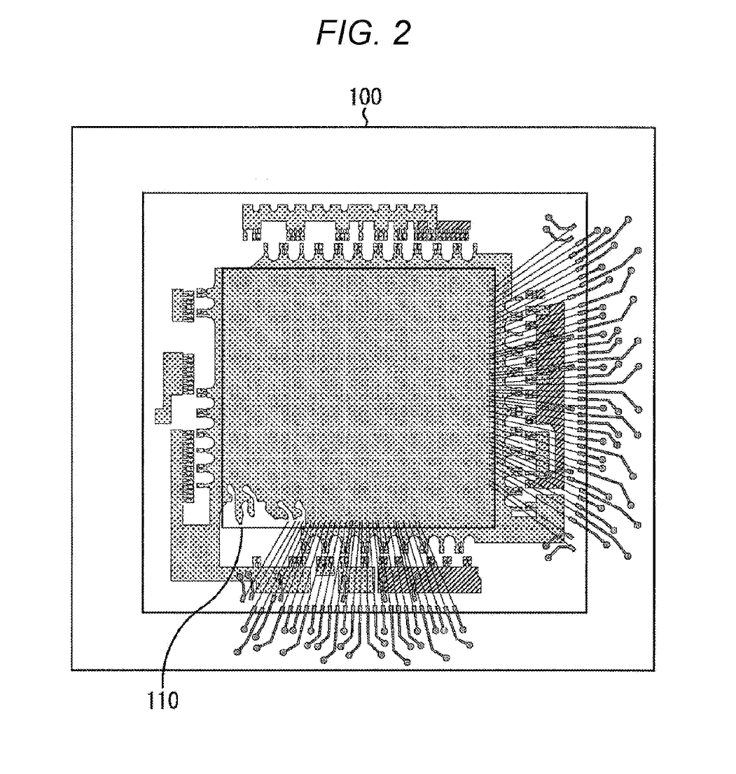

FIG. 2 is a view showing an example of a wiring pattern of the L1 layer of the multilayer printed circuit board of the related art. As shown in FIG. 2, an area (referred to as a chip lower area) 110 located under the chip 22 in the wiring pattern 100 of the L1 layer is a ground (GND) plane.

A plane is a film of a conductor printed on a multilayer printed circuit board but is a conductor film that is not patterned, and refers to what is called a solid area having a large area of a predetermined value or larger. With a multilayer printed circuit board of the related art, it is not easy to prevent the source impedance from increasing. When a multilayer printed circuit board is used for a DDR2 memory or the like, an increase in the impedance of the printed circuit board is a factor that worsens simultaneous switching output noise (SSO) jitter, that is, jitter caused by simultaneous switching noise, clock jitter, noise between a power supply and the ground, and the like.

Furthermore, as the data transfer rate becomes higher, it is increasingly difficult to suppress jitter of a signal so that a multilayer printed circuit board is compatible with a standard such as the DDR, and it is necessary to improve the source impedance characteristics of multilayer printed circuit boards.

In the multilayer printed circuit of the related art, however, the chip lower area of the L1 layer is a GND plane and the power layer is only the L3 layer as shown in FIG. 1, which makes it difficult to improve the impedance characteristics of the power supply wiring between solder balls and the pads on the chip 22. Specifically, since the total area of the power plane is smaller than that of the GND plane, the impedance of the power supply wiring between the solder balls and the pads on the chip 22 is high.

Furthermore, in the multilayer printed circuit board of the related art, since the pads are placed so that wire bonding to GND becomes shortest in preference to the power supply, wiring between the solder balls and the pads on the chip 22 is long, which still makes it difficult to improve the source impedance characteristics. The present technology therefore enables the impedance characteristics of power supply wiring to be improved in a multilayer printed circuit board.

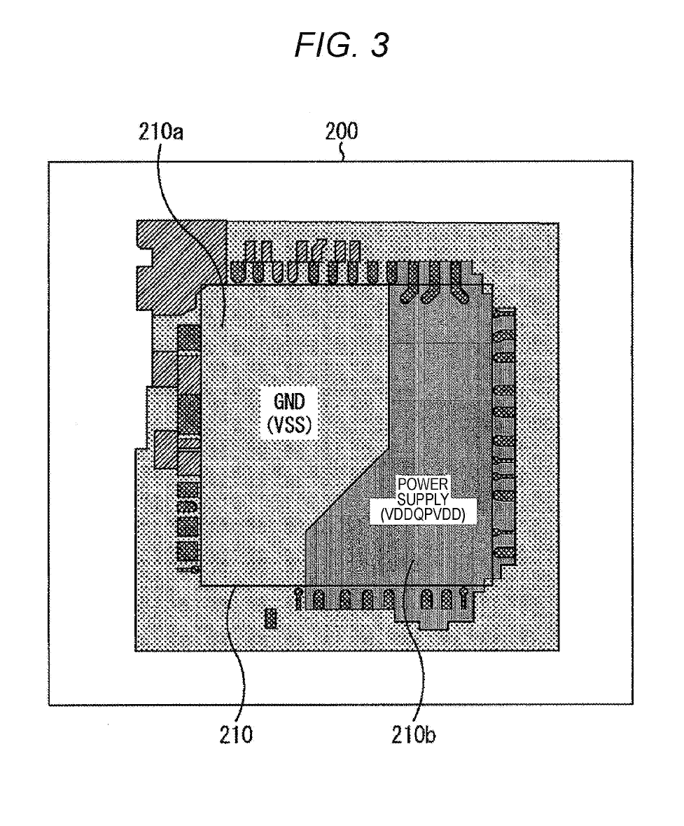

FIG. 3 is a view showing an example of a wiring pattern of the L1 layer of a multilayer printed circuit board to which the present technology is applied.

As shown in FIG. 3, a chip lower area 210 in a wiring pattern 200 of the L1 layer includes a GND plane 210a and a power plane 210b. Thus, the power plane is included in the chip lower area unlike the wiring pattern on the L1 layer of the multilayer printed circuit board of the related art.

Note that a plane such as the power plane and the GND plane is a film of a conductor printed on a multilayer printed circuit board but is a conductor film that is not patterned, and refers to what is called solid having a large area of a predetermined value or larger.

Although details will be provided later, there are three types of power supplies of a multilayer printed circuit board, which are a DDR power supply (VDDQPVDD), a core power supply (VDD_CORE), and other power supplies. The power plane 210b is a DDR power supply.

This allows the total area of the DDR power plane to be larger, which makes it possible to suppress the impedance of the power supply wiring between the solder balls and the pads on the chip 22 to be low.

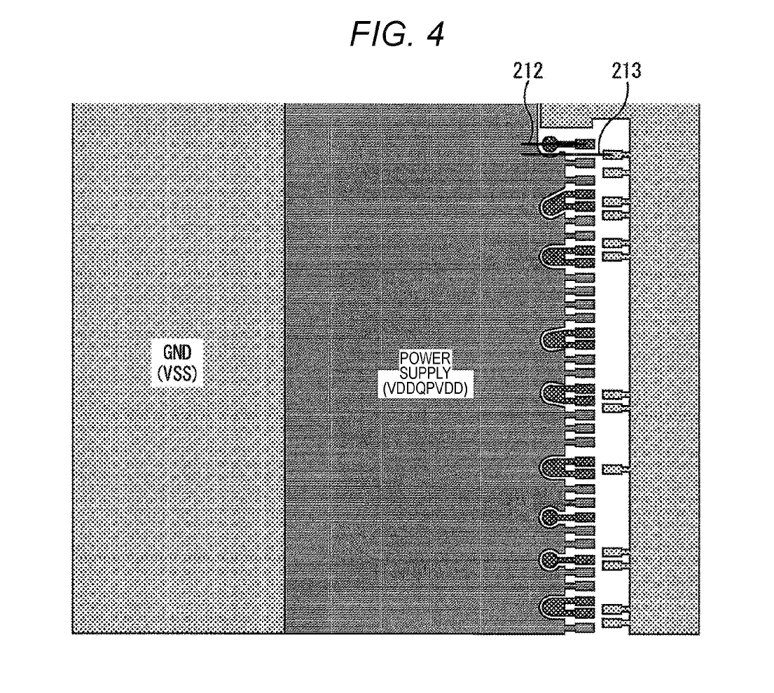

FIG. 4 is an enlarged view of an upper-right part of the chip lower area 210 in FIG. 3. Although not shown in FIG. 4, a chip is provided on each of the power plane and the GND plane. Then, power supply wiring, GND wiring, signal line wiring and the like are provided by wire bonding between the pads on the chip and the front face (that is, the L1 layer of the interposer 21. As shown in FIG. 4, a power supply wire 212 is shorter than a GND wire 213 in the multilayer printed circuit board to which the present technology is applied. Details of wiring and relative positions of the pads and the solder balls in the multilayer printed circuit board to which the present technology is applied will be provided later.

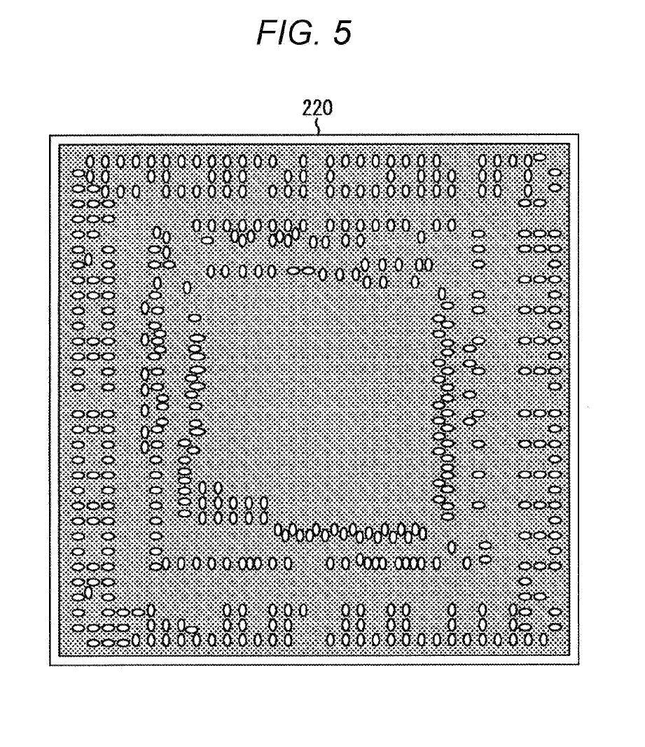

FIG. 5 is a view showing an example of a wiring pattern of the L2 layer of the multilayer printed circuit board to which the present technology is applied. The L2 layer of the multilayer printed circuit board to which the present technology is applied is a ground layer.

As shown in FIG. 5, a wiring pattern 220 of the L2 layer is a GND plane.

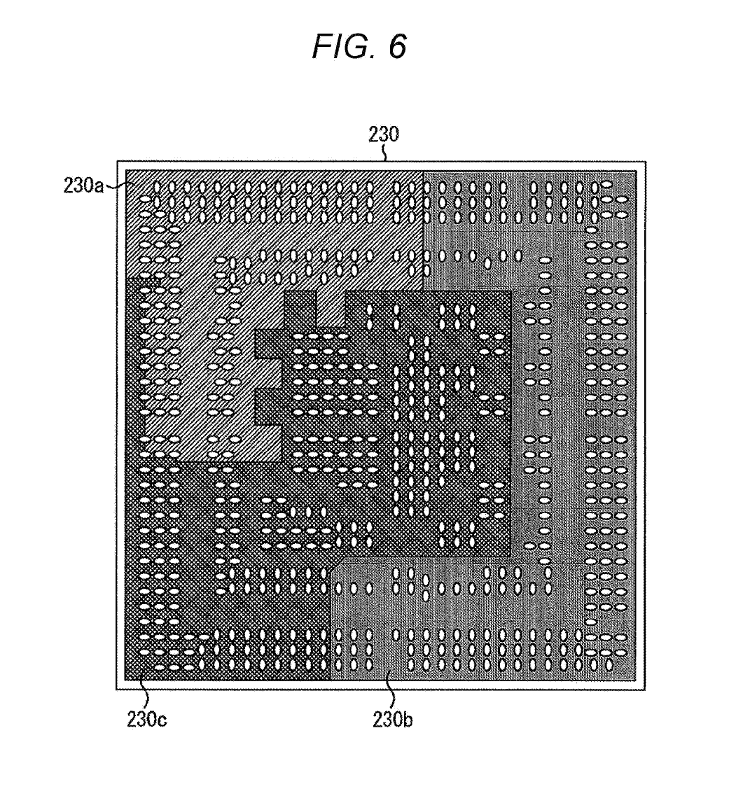

FIG. 6 is a view showing an example of a wiring pattern of the L3 layer of the multilayer printed circuit board to which the present technology is applied. The L3 layer of the multilayer printed circuit board to which the present technology is applied is a power layer.

Regarding the DDR power supply according to the present technology, since the power planes are present in the L1 layer and the L3 layer, it is possible to reduce the impedance by coupling the power planes with the GND plane of the L2 layer.

As shown in FIG. 6, a wiring pattern 230 of the L3 layer includes three types of power planes. Specifically, the wiring pattern 230 includes an other power plane 230a, a DDR power plane 230b, and a core power plane 230c. The other power supply, the DDR power supply and the core power supply have different voltages.

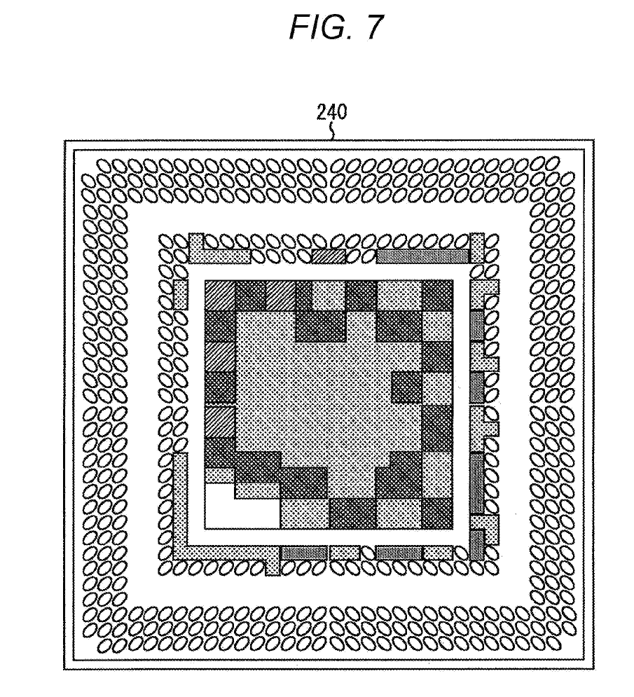

FIG. 7 is a view showing an example of a wiring pattern of the L4 layer of the multilayer printed circuit board to which the present technology is applied. The L4 layer of the multilayer printed circuit board to which the present technology is applied is a solder ball layer, and solder balls are arranged as necessary on a wiring pattern 240 of the L4 layer.

Next, the wiring and the relative positions of the pads and the solder balls in the multilayer printed circuit board to which the present technology is applied will be described in detail.

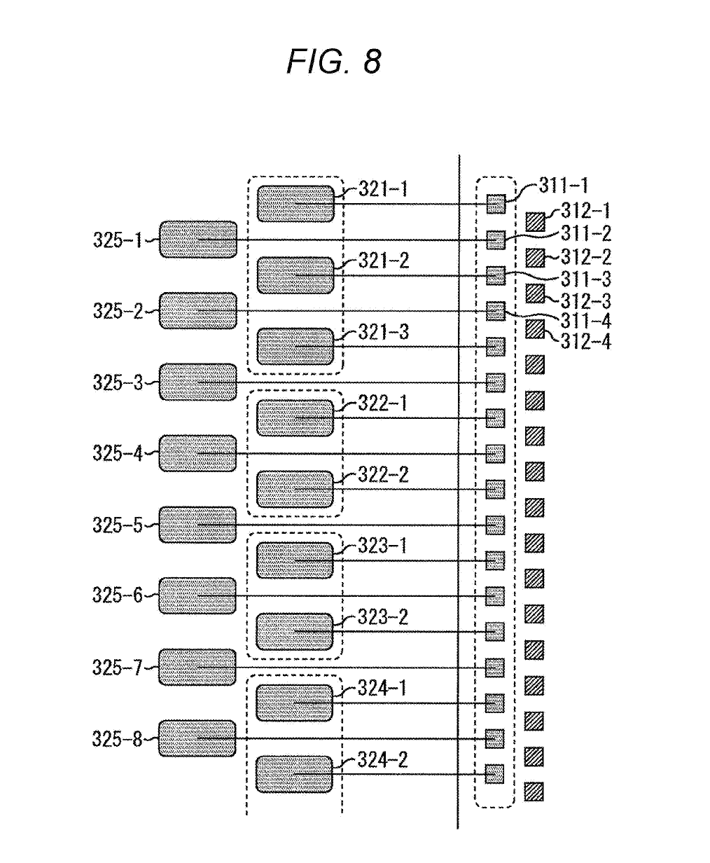

FIG. 8 is a diagram showing an exemplary schematic arrangement of the pads on the chip and the second pads on the L1 layer of the multilayer printed circuit board to which the present technology is applied.

In FIG. 8, pads 311-1, 311-2, 311-3, 311-4, . . . are the pads on the chip that serve as pads for power supply. Furthermore, pads 312-1, 312-2, 312-3, 312-4, . . . are the pads on the chip that serve as pads for signal lines. Note that the pads 311-1, 311-2, 311-3, 311-4, . . . will be collectively referred to as pads 311 when the pads need not be distinguished individually. Similarly, the pads 312-1, 312-2, 312-3, 312-4, . . . will be collectively referred to as pads 312 when the pads need not be distinguished individually.

Furthermore, second pads 321-1, 321-2, 321-3, 322-1, . . . , 323-1, . . . , 324-1, . . . , 325-1, . . . , and 325-8 are second pads on the L1 layer that serve as second pads for power supply. Note that these pads will be collectively referred to as second pads 321, second pads 322, second pads 323, second pads 324, or second pads 325, when the pads need not be distinguished individually.

As shown in FIG. 8, the pads 311 for power supply on the chip are arranged outside (near the outer circumference of the rectangular chip) of the pads 312 for signal lines. Specifically, the pads 311 for power supply are arranged at the edge of the chip so that the length of wires for wire bonding between the pads 311 for power supply and the second pads on the L1 layer becomes as short as possible. Thus, the pads 311 for power supply are arranged near the edge of the chip at a very short distance to the L1 layer. As a result, it is possible to suppress the impedance of power supply wiring to be low. Furthermore, in FIG. 8, the second pads 321 serve as second pads for VDDQPVDD (DDR power supply), and the second pads 322 serve as second pads for VDD_CORE (core power supply). Moreover, the second pads 323 serve as second pads for VDDQPVDD (DDR power supply), and the second pads 324 serve as second pads for VDD_CORE (core power supply).

In the present technology, the second pads for the DDR power supply and the second pads for the core power supply are arranged on the right in the drawing. Specifically, the second pads for power supply are arranged at positions near the edge of the chip on the L1 layer.

Three second pads 321 are connected together to another layer through one via. Two second pads 322 are connected together to another layer through one via. Furthermore, two second pads 323 are connected together to another layer through one via. Two second pads 324 are connected together to another layer through one via.

Thus, in the multilayer printed circuit board to which the present technology is applied, second pads for the same type of power supply are arranged together as much as possible. Thus, second pads for the same type of power supply are arranged adjacent to one another as much as possible so that multiple second pads can be connected together through one via.

This can reduce the total number of vias provided in the power plane and prevent the total area of the power plane from decreasing because of the vias. As a result, it is still possible to suppress the impedance of power supply wiring to be low.

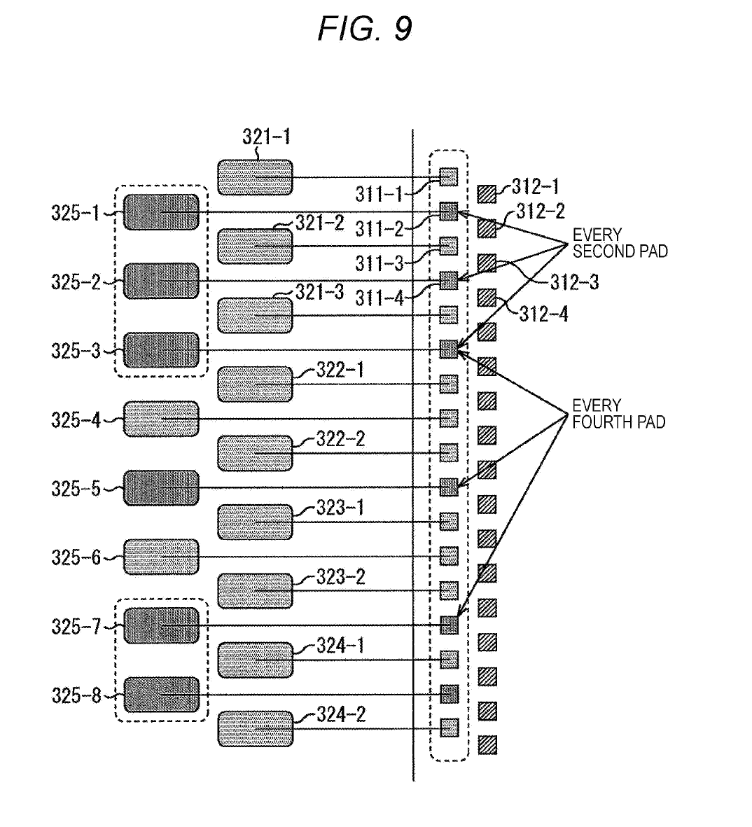

FIG. 9 is a diagram showing an exemplary schematic arrangement in which pads for GND are arranged on an outer side of the chip similarly to the pads for power supply.

In the example of FIG. 9, a pad 311-1 is a pad for power supply, a pad 311-2 is a pad for GND, a pad 311-3 is a pad for power supply, and a pad 311-4 is a pad for GND. Furthermore, in FIG. 9, second pads 325-1 to 325-3 are second pads for GND, a second pad 325-4 is a second pad for power supply, and a second pad 325-5 is a second pad for GND. Moreover, a second pad 325-6 is a second pad for power supply, and second pads 325-7 and 325-8 are second pads for GND.

Then, the second pads 325-1 to 325-3 are connected together to another layer through one via, and the second pads 325-7 and 325-8 are connected together to another layer through one via, for example.

Thus, in the multilayer printed circuit board to which the present technology is applied, second pads for GND are arranged together as much as possible. Thus, second pads for GND are arranged adjacent to one another as much as possible so that multiple second pads can be connected together through one via.

This can reduce the total number of vias provided in the power plane or the GND plane and prevent the total area of the power plane or the GND plane from decreasing because of the vias. As a result, it is still possible to suppress the impedance of power supply or GND wiring to be low.

Furthermore, when a through-hole board is used as the multilayer printed circuit board, for example, the arrangement of vias is strictly limited. Thus, the flexibility of circuit design can be increased by reducing the total number of vias provided in the power plane to be as small as possible. Moreover, a low-cost through-hole board can be more easily employed instead of a high-cost build-up board in the structure of the multilayer printed circuit board. It is therefore also possible to reduce the cost of the multilayer printed circuit board according to the present technology.

Furthermore, pads for GND are not arranged continuously on the chip so that second pads for GND can be arranged together as much as possible on the L1 layer as described above. Specifically, among the pads 311 arranged on an outer side of the chip, two or more GND pads are not arranged adjacent to each other and one or more power supply pads are always arranged between GND pads.

For example, in the example of FIG. 9, the GND pads are arranged at intervals of “every second pad” or “every fourth pad” on the chip and pads adjacent to both sides of a GND pad are always power supply pads. As a result, the wires for the power supply and the GND are coupled so that the impedance is reduced.

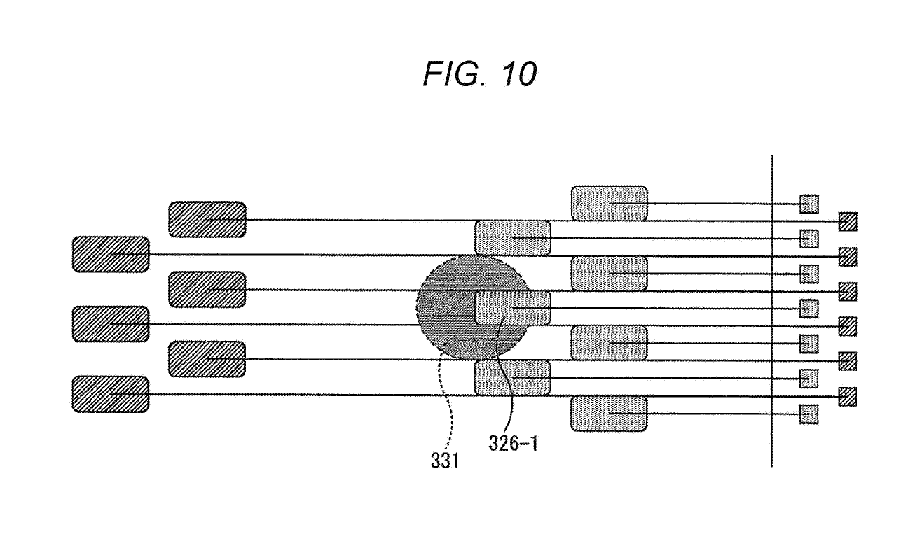

Furthermore, in the present technology, solder balls are arranged near the second pads for power supply on the rear face of the L4 layer. For example, a solder ball 331 is arranged near a second pad 326-1 for power supply as shown in FIG. 10. In FIG. 10, note that the second pad 326-1 is provided on the front face of the L1 layer while the solder ball 331 is provided on the rear face of the L4 layer.

Although only the solder ball 331 is shown, solder balls are also arranged as necessary near other second pads for power supply.

Thus, in the present technology, solder balls are arranged at positions on the L4 layer corresponding to the positions where the second pads for power supply are arranged on the L1 layer. For example, when the positions on front faces of the layers of the multilayer printed circuit board having the same rectangular shape are expressed using two-dimensional coordinates, the solder balls on the L4 layer are arranged at substantially the same coordinate positions as those of the second pads for power supply on the L1 layer.

As a result of arranging the solder balls near the second pads for power supply in this manner, power supply wiring between the solder balls and the pads on the chip can be shortened and the impedance of the power supply wiring can be suppressed to be low.

The structure of the multilayer printed circuit board to which the present technology is applied can reduce simultaneous switching noise (SSN) that may have influence on the circuit operation.

When the voltage of SSN is represented by V, the number of simultaneous data operations represented by N, and the effective inductance of power supply is represented by L, V can be obtained by the following equation (1):

[Math. 1]

V=N*L*di/dt (1).

In the equation (1), di/dt represents the value of current driven per unit time by an I/O buffer.

The equation (1) shows that the circuit can be structured so that the inductance value becomes as small as possible if the simultaneous switching noise (SSN) of the circuit is to be reduced.

Furthermore, the structure of the multilayer printed circuit board to which the present technology is applied can suppress the impedance that worsens the power supply characteristics.

An ideal inductor having an inductance value of L has a reactance X determined by the impedance XL=2πfL with respect to frequency f and has a resistance of 0. Thus, it can be seen that the impedance is larger as the inductance value is larger. Furthermore, an ideal capacitor having a capacitance value of C has a reactance X determined by the impedance XC=−1/(2πfC) with respect to frequency f and has a resistance of 0. Thus, it can be seen that the impedance is smaller as the capacitance value is larger.

Accordingly, if the impedance of circuit wiring is to be suppressed to be low, the inductance value of the circuit is made as small as possible and the capacitance value thereof is made as large as possible.

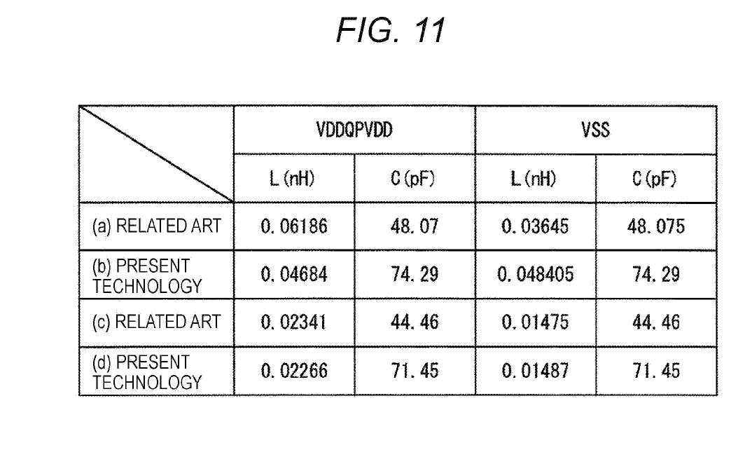

FIG. 11 is a table showing results of measuring the inductance value L and the capacitance value C of each of the DDR power supply (VDDQPVDD) and the GND (VSS) in a package substrate structured using a multilayer printed circuit board and a chip to which the present technology is applied. Note that FIG. 11 also shows results of measuring the inductance value L and the capacitance value C of each of the DDR power supply (VDDQPVDD) and the GND (VSS) in a package substrate structured using a multilayer printed circuit board and a chip of the related art for reference.

In FIG. 11, results of measuring the inductance value L and the capacitance value C of the package substrate of the related art are shown on a row (a). In FIG. 11, results of measuring the inductance value L and the capacitance value C of the package substrate to which the present technology is applied are shown on a row (b).

Furthermore, in FIG. 11, results of measuring the inductance value L and the capacitance value C of the package substrate of the related art in a state in which the chip (wires) is removed are shown on a row (c).

Furthermore, in FIG. 11, results of measuring the inductance value L and the capacitance value C of the package substrate to which the present technology is applied in a state in which the chip (wires) is removed are shown on a row (d).

As a result of obtaining results of measurement of a package substrate in a state in which the chip (wires) is removed, it is possible to measure changes in the inductance value and the capacitance value resulting from applying the present technology in a state in which the influence of the wire length is removed. In other words, attention can be paid to the effect of arranging a power plane on the L1 layer as described above with reference to FIG. 3.

As can be seen from (a) and (b) of FIG. 11, the inductance value of the power supply increases while the capacitance value decreases as a result of applying the present technology. Furthermore, as can be seen from (c) and (d) of FIG. 11, the inductance value of the power supply slightly decreases while the capacitance value increases as a result of applying the present technology. Therefore, it can be seen that the simultaneous switching noise can be reduced and the impedance of power supply can be suppressed to be low as a result of applying the present technology as compared to the package substrate of the related art. Note that unnecessary radiation (electro-magnetic interference: EMI) can also be reduced as a result of the reduction in the simultaneous switching noise.

Furthermore, as can be seen in (a) to (d) of FIG. 11, the inductance value of the GND slightly increases while the capacitance value also increases greatly as a result of applying the present technology.

Therefore, it can be seen that the impedance of the GND does not increase greatly as a result of applying the present technology as compared to the package substrate of the related art.

Furthermore, as described above, the simultaneous switching noise can also be reduced as a result of applying the present technology. Thus, it is also possible to reduce bypass capacitors provided on the motherboard for reducing the simultaneous switching noise in the related art. In other words, the cost of the motherboard can also be reduced.

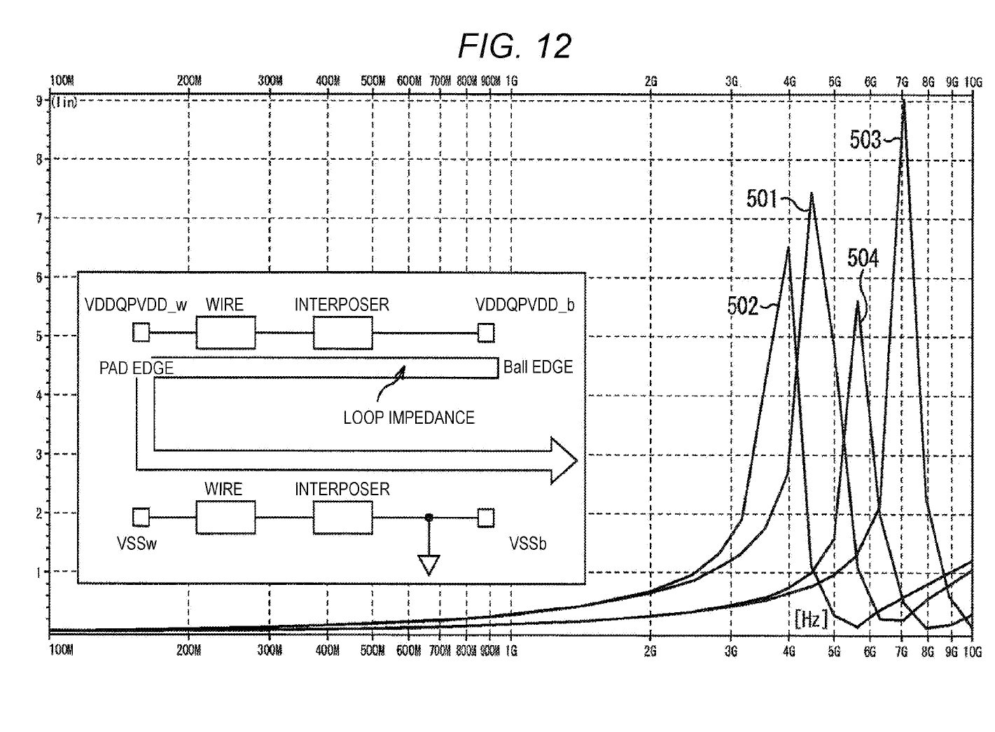

FIG. 12 shows a result of measuring loop impedance of a path between a solder ball (Ball) edge of the power supply (VDDQb) and a solder ball (Ball) edge of the GND (VSSb) in a package substrate structured using a multilayer printed circuit board and a chip to which the present technology is applied.

In FIG. 12, the vertical axis represents the impedance value, the horizontal axis represents frequency, lines 501 to 504 represents changes in the impedance value with changes in frequency.

In FIG. 12, the line 501 represents the loop impedance in a package substrate of the related art. The line 502 represents the loop impedance in a package substrate to which the present technology is applied.

Furthermore, in FIG. 12, the line 503 represents the loop impedance in the package substrate of the related art in which the chip (wires) is removed. In FIG. 12, the line 504 represents the loop impedance in the package substrate to which the present technology is applied in a state in which the chip (wires) is removed.

As a result of obtaining results of measurement of a package substrate in a state in which the chip is removed, it is possible to measure changes in the loop impedance resulting from applying the present technology in a state in which the influence of the wire length is removed. In other words, attention can be paid to the effect of arranging a power plane on the L1 layer as described above with reference to FIG. 3.

The line 502 has a lower peak of the impedance value as compared to the line 501, which shows that the impedance characteristics are improved by the present technology.

Furthermore, the line 504 has a lower peak of the impedance value as compared to the line 503, which shows that the impedance characteristics are improved by the present technology.

According to the present technology, since the impedance characteristics are improved in this manner, it is not necessary to provide an additional power layer for improving the impedance characteristics as in the multilayer printed circuit board of the related art. It is therefore possible to reduce the number of layers of a multilayer printed circuit board by using the present technology, in such a manner that an eight-layer or six-layer printed circuit board of the related art can be structured as a six-layer or four-layer printed circuit board.

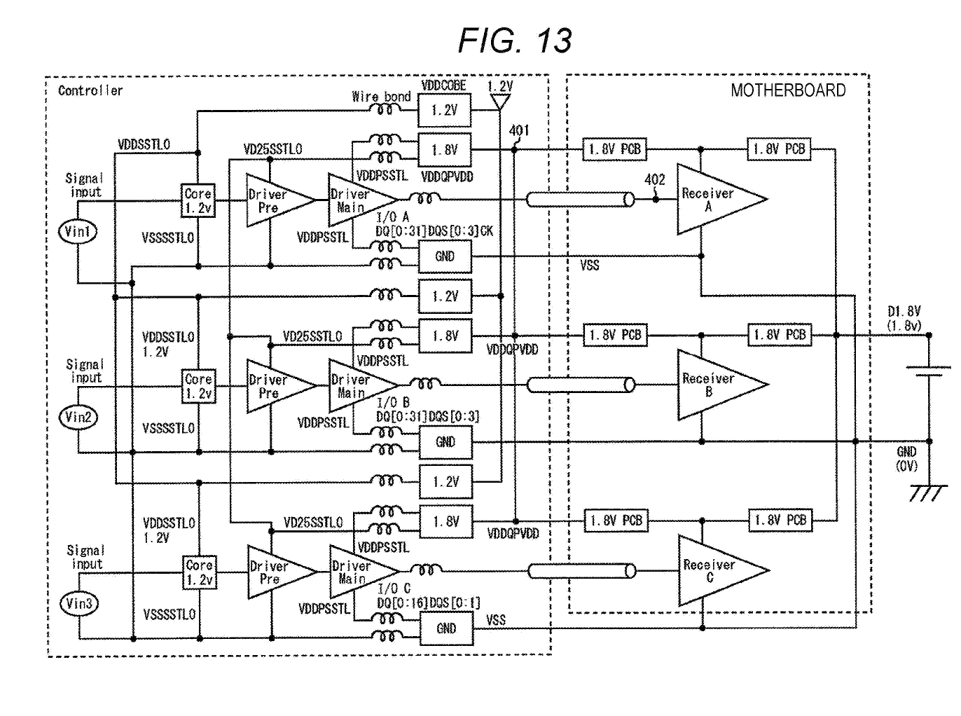

FIG. 13 is a circuit diagram of a package substrate to which the present technology is applied and which serves as an LSI of a DDR memory. The circuit shown in FIG. 13 can simultaneously transfer 80-bit data. Signal waveforms (eye patterns) when 80-bit data is recorded simultaneously are measured at measurement points 401 and 402 in the circuit of FIG. 13.

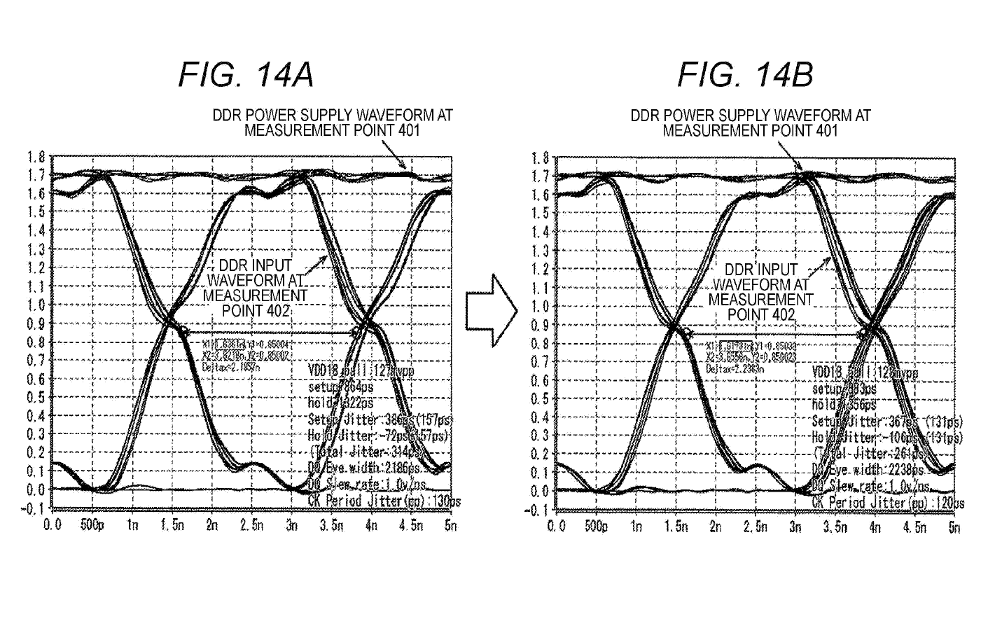

FIGS. 14A and 14B are graphs showing the eye patterns obtained as described above with the circuit of FIG. 13.

In FIGS. 14A and 14B, the vertical axis represents voltage and the horizontal axis represents time. Note that eye patterns (of a DDR input terminal) when the circuit is operated with a transfer rate of 400 Mbps, a DDR power supply of 1.7 V, and a core power supply of 1.1 V are shown here. FIG. 14A shows an eye pattern in a package substrate of the related art, and FIG. 14B shows an eye pattern in a package substrate to which the present technology is applied.

An opening in the eye pattern of FIG. 14A is shown by a horizontal arrow in the drawing, which has 2.1857 ns (=3.8218−1.6361). An opening in the eye pattern of FIG. 14B is shown by a horizontal arrow in the drawing, which has 2.2383 ns (=3.8556−1.6173). Thus, the opening is larger and the power supply characteristics are improved in the package substrate of the present technology as compared with that of the related art.

Furthermore, in the package substrate to which the present technology is applied, the setup jitter and the total jitter are improved by 19 ps and 53 ps, respectively, and again, the power supply characteristics are improved as compared to the package substrate of the related art.

In the example of FIG. 3 described above, the chip lower area 210 of the wiring pattern 200 of the L1 layer includes the GND plane 210a and the power plane 210b. In the present technology, however, the chip lower area 210 in the wiring pattern 200 of the L1 layer may include only a power plane.

Furthermore, embodiments of the present technology are not limited to the embodiments described above, but various modifications may be made thereto without departing from the scope of the technology.

The present technology can also have the following structures.

(1)

A multilayer printed circuit board having multiple layers, including: a chip mounted on a top layer of the printed circuit board; and at least a conductor connected to a power supply and a conductor connected to a ground as conductors printed on the respective layers, wherein a power plane that is the conductor connected to the power supply and that is not patterned is provided on a lower area of the chip on the top layer.

(2)

The printed circuit board described in (1), wherein out of second pads wire-bonded to pads on the chip provided on the top layer, a first second pad wire-bonded to a pad connected to the power supply is arranged nearer to an edge of the chip than a second second pad wire-bonded to a pad connected to the ground.

(3)

The printed circuit board described in (2), wherein multiple solder balls are provided on a bottom layer opposite to the top layer of the multilayer printed circuit board, and when positions on front surfaces of the respective layers of the multilayer printed circuit board having identical rectangular shapes, the positions corresponding to those of the first second pads on the top layer, are expressed by using two-dimensional coordinates, the solder balls on the bottom layer are provided at substantially same coordinate positions as those where the first second pads are arranged on the top layer.

(4)

The printed circuit board described in any one of (1) to (3), wherein out of second pads wire-bonded to pads on the chip provided on the top layer, multiple second pads wire-bonded to pads connected to power supplies of equal voltage are arranged close to one another as a group of second pads, and the group of second pads is connected to another layer through one via.

(5)

The printed circuit board described in any one of (1) to (4), wherein the chip on which pads connected to the power supply are arranged at an outermost portion of and in parallel to an edge of the chip is mounted on the top layer.

(6)

The printed circuit board described in (5), wherein the pads arranged at the outermost portion of the chip include pads connected to the ground, and pads adjacent to both sides of the pads connected to the ground are pads connected to the power supply.

### REFERENCE SIGNS LIST

10 Package substrate

21 Interposer

22 Chip

31 Wire

32 Resin

41 Solder ball

200 Wiring pattern

210 Chip lower area

212 Power supply wire

213 GND wire

311 Pad

312 Pad

321 to 325 Second pad

1. A multilayer printed circuit board having multiple layers, comprising:
a chip mounted on a top layer of the printed circuit board; and
at least a conductor connected to a power supply and a conductor connected to a ground as conductors printed on the respective layers, wherein
a power plane that is the conductor connected to the power supply and that is not patterned is provided on a lower area of the chip on the top layer.

2. The printed circuit board according to claim 1, wherein
out of second pads wire-bonded to pads on the chip provided on the top layer, a first second pad wire-bonded to a pad connected to the power supply is arranged nearer to an edge of the chip than a second pad wire-bonded to a pad connected to the ground.

3. The printed circuit board according to claim 2, wherein
multiple solder balls are provided on a bottom layer opposite to the top layer of the multilayer printed circuit board, and
when positions on front surfaces of the respective layers of the multilayer printed circuit board having identical rectangular shapes, the positions corresponding to those of the first second pads on the top layer, are expressed by using two-dimensional coordinates, the solder balls on the bottom layer are provided at substantially same coordinate positions as those where the first second pads are arranged on the top layer.

4. The printed circuit board according to claim 1, wherein out of second pads wire-bonded to pads on the chip provided on the top layer,
multiple second pads wire-bonded to pads connected to power supplies of equal voltage are arranged close to one another as a group of second pads, and
the group of second pads is connected to another layer through one via.

5. The printed circuit board according to claim 1, wherein the chip on which pads connected to the power supply are arranged at an outermost portion of and in parallel to an edge of the chip is mounted on the top layer.

6. The printed circuit board according to claim 5, wherein the pads arranged at the outermost portion of the chip include pads connected to the ground, and pads adjacent to both sides of the pads connected to the ground are pads connected to the power supply.
